(19) United States
(12) Patent Application Publication
(10) Pub. No.: US 2012/0224339 A1
(43) Pub. Date: Sep. 6, 2012

(54) TERMINAL BOX FOR USE WITH SOLAR CELL MODULE AND METHOD OF MANUFACTURING THE TERMINAL BOX

(75) Inventors: Hiroyuki Yoshikawa, Yokkaichi-shi (JP); Masayoshi Hashimoto, Yokkaichi-shi (JP); Makoto Higashikozono, Yokkaichi-shi (JP); Tomoya Kawaguchi, Yokkaichi-shi (JP)

(73) Assignee: SUMITOMO WIRING SYSTEMS, LTD., Yokkaichi-shi (JP)

(21) Appl. No.: 13/503,035

(22) PCT Filed: Jul. 29, 2010
(86) PCT No.: PCT/JP2010/062769

§ 371 Date: Apr. 20, 2012

(30) Foreign Application Priority Data
Nov. 20, 2009 (JP) 2009-265384

(51) Int. Cl. H05K 7/02; H05K 13/00

(52) U.S. Cl. 361/752; 29/825

(57) ABSTRACT

A terminal box for a solar cell module, has terminal boards (10). A bypass diode (30) is connected between corresponding terminal boards (10) and serves as a bypass for a reverse load. A box main body (50) houses the bypass diode (30) and the terminal boards (10) and has an opening (58). A cover (70) is fit to the box main body (50) to cover the opening (58) and has a protrusion (71) on the back surface. An insulating resin (60) is introduced into the box main body (50) before the cover (70) is fit to the box main body (50) and has a recess (61) the surface of which contacts the outer surface of the protrusion (71) after the cover (70) is fit to the box main body (50).

### BACKGROUND OF THE INVENTION

1. Field of the Invention

The present invention relates to a terminal box for use with solar cell module and a method of manufacturing the terminal box.

2. Description of the Related Art

A conventional terminal box for use with a solar cell module includes a plurality of terminal boards, bypass diodes connecting corresponding terminal boards together respectively, a box main body housing the terminal boards and the bypass diodes and a cover which is disposed so as to cover an open side of the box main body. A metal member is formed on an underside of the cover.

An insulating resin is introduced into the box main body, and the cover is attached to the box main body after the insulating resin has been hardened. As a result, heat generated by the bypass diodes is dissipated from the insulating resin through the metal member and the cover to the atmosphere.

Japanese Patent Application Publication No. JP-A-2007-27162 is an example of the state-of-the-art described above.

The metal member is abutted on the surface of the insulating resin in order that the metal member may exert a sufficient heat-transfer performance in the above-described conventional terminal box. However, in the method of attaching the cover to the box main body after the hardening of the insulating resin, it is difficult to reliably abut the metal member on the surface of the insulating resin. As a result, an air space is necessarily interposed between the metal member and the surface of the insulating resin, resulting in a concern that the air space virtually breaks off a heat dissipation path leading to the cover. Consequently, since heat generated by the bypass diodes is not sufficiently transferred to the cover, it is difficult to efficiently dissipate heat to the atmosphere.

The present invention was made in view of the foregoing circumstances and an object thereof is to ensure a desirable heat dissipation path to the atmosphere.

### SUMMARY OF THE INVENTION

The present invention is a terminal box for use with a solar cell module, which is mounted on a solar cell module, the terminal box comprising a plurality of terminal boards, a bypass rectifying device for reverse load, connected to the corresponding terminal boards, a box main body housing the rectifying device and the terminal boards and having an open side, a cover which is attached to the box main body so as to cover the open side of the box main body and has an underside having a protrusion, and an insulating resin which is introduced into the box main body before the cover is attached to the box main body, the insulating resin having a surface formed with a recess which is abutted along an outer surface of the protrusion when the cover is attached to the box main body.

Since the recess is brought into abutment along the outer surface of the protrusion, an air space is prevented from being interposed between the insulating resin and the cover. Consequently, heat generated by the rectifying devices is efficiently dissipated from the insulating resin through the cover into the atmosphere.

The terminal box for use with the solar cell module may have the configurations described in the following paragraphs.

The protrusion may be formed integrally with the cover. Consequently, the number of parts can be prevented from being increased.

The cover may have a surface having a depressed portion formed at a position opposed to the protrusion. Consequently, an increase in the thickness of the cover can be avoided and an occurrence of sink mark during the forming of the cover can be suppressed.

The depressed portion may have heat dissipation fins formed therein. According to this, heat dissipation to the atmosphere can be carried out more efficiently.

The protrusion and the recess may be disposed at respective positions opposed to the rectifying devices. Consequently, heat generated by the rectifying devices is efficiently transferred to the protrusion.

Plural rectifying devices may be lined in one direction in the box main body, and the protrusion and the recess may be formed to be elongate in the one direction in which the rectifying deices are arranged. According to this, the protrusion and the recess can be avoided from respective complicated shapes and the terminal box excels in the heat dissipation efficiency.

The rectifying device may be supported on one of the terminal boards, and said one terminal board has a supporting portion on which the rectifying device is supported, the supporting portion having a level raised to the protrusion side. Consequently, the rectifying device and the protrusion come close to each other, whereupon heat generated by the rectifying device is transferred to the protrusion more efficiently.

Furthermore, the invention is a method of manufacturing a terminal box for use with a solar cell module, the terminal box comprising a plurality of terminal boards, a bypass rectifying device for reverse load, connected to the corresponding terminal boards, a box main body housing the rectifying device and the terminal boards and having an open side, a cover which is attached to the box main body so as to cover the open side, the method comprising introducing an insulating resin into the box main body, and attaching the cover to the box main body before the insulating resin is hardened and adhering the insulating resin to an underside of the cover with attachment of the cover to the box main body.

The cover is attached to the box main body before the insulating resin is hardened. Since the insulating resin is adhered to the underside of the cover with attachment of the cover, an air space can reliably be prevented from being interposed between the cover and the insulating resin by a simple manner.

In this case, the method of manufacturing the terminal box for use with the solar cell module may have the following addition steps.

The cover may have an underside formed with a protrusion, and the protrusion may press a surface of the insulating resin with attachment of the cover to the box main body, whereby a recess is formed in a surface of the insulating resin. In the invention, since the cover is attached to the box main body before the insulating resin is hardened, the surface location of the insulating resin rises with attachment of the cover to the insulating resin, so that there is a possibility that the insulating resin may leak from the peripheral edge of the cover to the box main body side. In the invention, however, even when the surface location of the insulating resin rises, the rise can be absorbed into a space around the protrusion between the underside of the cover and the surface of the insulating resin. Consequently, the insulating resin can be prevented from leaking from the peripheral edge of the cover.

An amount of the insulating resin introduced into the box main body may be adjusted so that an interspace is defined between a part of the underside of the cover other than the protrusion and a part of the surface of the insulating resin other than the recess with the cover having being attached to the box main body. According to this, the insulating resin does not leak from the peripheral edge of the cover.

According to the invention, a desirable heat dissipation path to the atmosphere can be ensured.

### BRIEF DESCRIPTION OF THE DRAWINGS

FIG. 1 is a plan view of a terminal box for use with a solar cell module, according to a first embodiment of the present invention, showing an interior of the terminal box before the cover is attached;

FIG. 2 is a sectional view of the terminal box;

FIG. 3 is a plan view of the terminal box; and

FIG. 4 is a plan view of the terminal box according to a second embodiment.

### DETAILED DESCRIPTION OF THE PREFERRED EMBODIMENTS

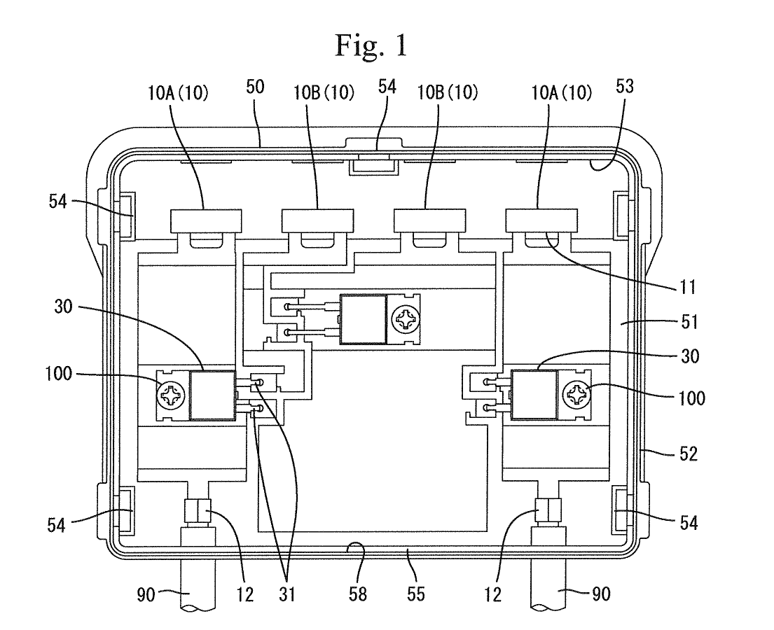

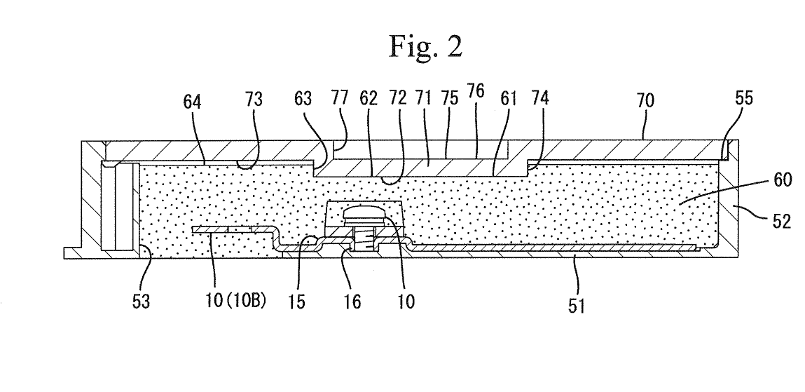

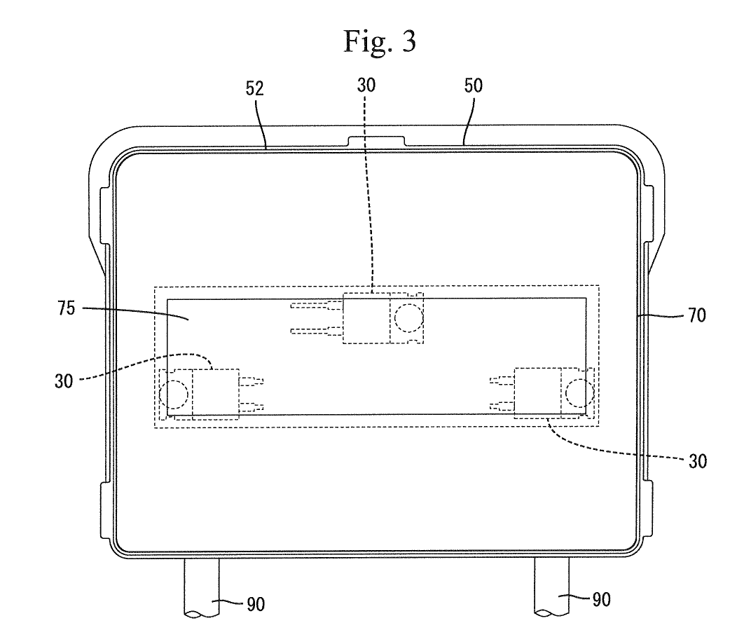

A first embodiment of the present invention will be described with reference to FIGS. 1 to 3. A terminal box for use with a solar cell module according to the first embodiment includes terminal boards 10, bypass diodes 30 (rectifying devices), a box main body 50 and a cover 70.

The box main body 50 is made of a synthetic resin and has a rectangular plate-shaped bottom wall 51 and a rectangular frame-shaped peripheral wall 52 rising from a peripheral edge of the bottom wall 51. The box main body 50 has an upper side serving as an opening 58 (an open side). The cover 70 is attached to the box main body 50 so as to cover the opening 58. The bottom wall 51 has an underside which is adhered closely to a mounting surface of a solar cell module which is not shown. The bottom wall 51 has an upper surface on which a plurality of terminal boards 10 is disposed so as to be lined in a widthwise direction (one direction). The bottom wall 51 has a front end formed with a window 53 which is open substantially over an entire width. Leads extending from cell groups of the solar cell module are drawn through the window 53 into the box main body 50.

The peripheral wall 52 has an inner peripheral surface on which a plurality of lock supports 54 is formed at intervals in the peripheral direction. The cover 70 has a cover lock (not shown) which is elastically locked by the lock supports 54, whereby the cover 70 is fixed to the box main body 50. Furthermore, the peripheral wall 52 has an upper end formed with a stepped portion 55 to which the peripheral edge of the cover 70 is fitted thereby to be supported.

Each terminal board 10 is an electrically conductive metal plate and is formed into the shape of a band plate. Each terminal board 10 comprises a pair of right and left cable connecting terminals 10A disposed at both widthwise ends of the bottom wall 51 and right and left relay connecting terminals 10B located between the cable connecting terminals 10A and disposed in the widthwise middle of the bottom wall 51, respectively. Each terminal board 10 has a front end having a connecting hole 11 formed therethrough. Lead is inserted into the connecting hole 11 and a terminal portion of the lead is soldered to each terminal board 10.

Both cable connecting terminals 10A have rear ends formed with barrel portions 12 respectively. The barrel portions 12 are crimped to terminal portions of cables 90 thereby to be connected to the cables 90 respectively. The cables 90 include a positive cable and a negative cable both corresponding to the cable connecting terminals 10A respectively. The cables 90 extend through the rear of the peripheral wall 52 thereby to be drawn out of the box main body 50.

The bypass diodes 30 for reverse load are mounted on one of the relay connecting terminals 10B (the right one as viewed in the drawings) and both cable connecting terminals 10A respectively. Each bypass diode 30 is formed into the shape of a square block made by enclosing a chip with a resin. The chip heats up as the result of exertion of a rectifying function and has a pair of lead legs 31 extending from an anode electrode and a cathode electrode thereof respectively. One of the lead legs 31 is soldered and connected to the terminal board 10 on which the bypass diode 30 is to be mounted, while the other lead leg 31 is soldered and connected to the neighboring terminal board 10. The bypass diodes 30 are fixed to the terminal boards 10 by screws 100 respectively. The terminal boards 10 includes portions supporting the bypass diodes 30 and have support portions 15 which are formed so as to rise toward a protrusion 71 which will be described later, respectively. As a result, the bypass diodes 30 are adapted to be disposed in proximity to the protrusion 71. The support portions 15 have undersides formed with burring portions 16 which protrude and are threadingly engaged with screws 100, respectively. As a result, the screws 100 can be threadingly engaged with the terminal boards 10 respectively.

The bypass diodes 30 are disposed so as to be lined widthwise in the central part of the bottom wall 51 of the box main body 50 with respect to the front-back direction. In more detail, the bypass diodes 30 supported by both cable connecting terminals occupy substantially the same position with respect to the front-back direction, and the bypass diode 30 supported on one of the relay connecting terminals 10B is located frontward relative to the bypass diodes 30 supported on both cable connecting diodes 10A respectively. As a result, thermal interference between the bypass diodes 30 can effectively be avoided.

One of the relay connecting terminals 10B and both cable connecting terminals 10A have functions as heat-dissipation plates dissipating heat generated by the chips of the bypass diodes 30 respectively. The relay connecting terminal 10B has a largest surface area of all the terminal boards 10, whereupon heat dissipation is improved in this portion. On the other hand, since the other relay connecting terminal 10B (the left one as viewed in the drawings) supports no bypass diode and does not directly involve in heat dissipation, this relay connecting terminal 10B has a smallest surface area of all the terminal boards 10. In other words, the smaller is rendered the aforementioned other relay connecting terminal 10B, the larger is rendered the aforementioned one relay connecting terminal 10B, whereby a desirable space efficiency is ensured.

The insulating resin 60 comprising a potting material such as silicon is introduced into the box main body 50. When cooled thereby to be solidified, the insulating resin 60 hermetically seals connections between the terminal boards 10 and the leads, connections between the bypass diodes 30 and the terminal boards 10 and connections between both cable connecting terminals 10A and the cables 90. The insulating resin 60 also has an action of transferring heat generated by the bypass diodes 30 to the cover 70 side.

The cover 70 is made of a synthetic resin and is formed into the shape of a rectangular flat plate sized to cover the opening 58 of the box main body 50.

The cover 70 has an underside further having a trapezoidal protrusion 71 which is formed in a central portion with respect to the front-back direction so as to protrude to the insulating resin 60 side. In more detail, the protrusion 71 is disposed at a location opposed to each bypass diode 30 and formed into a widthwise elongate rectangular shape in bottom view so as to lump the bypass diodes 30. The protrusion 71 has an underside (a protruding end surface) which serves in its entirety as a first horizontal surface 72 which is generally horizontal and flat. The underside of the cover 70 includes a portion around the protrusion 71, that is, the portion other than the protrusion 71. The portion of the cover underside is formed with a second horizontal surface 73 which is generally horizontal and flat. The second horizontal surface 73 is continuous to the first horizontal surface 72 with a stepped surface being interposed therebetween. The stepped surface serves as a first vertical surface 74 rising substantially vertically over the entire circumference thereof.

A stepped recess 61 is formed in an upper surface of the insulating resin 60 along an outer surface of the protrusion 71 when the cover 70 is attached to the box main body 50. More specifically, the recess 61 is formed into a shape fit into the protrusion 71 and has a third horizontal surface 62 which is closely adhered to the first horizontal surface 72 and a second vertical surface 63 which is closely adhered to the first vertical surface 74. The second vertical surface 63 has a smaller height (a projection of the protrusion 71) than the first vertical surface 74 (the depth of the recess 61). A fourth horizontal surface 64 is formed around the recess 61 on the upper surface of the insulating resin 60, that is, on a part of the upper surface of the insulating resin 60 other than the recess 61, and is continuous to an upper end of the second vertical surface 63. The fourth horizontal surface 64 is disposed substantially in parallel with the second horizontal surface 73 and has a space between the second horizontal surface 73 and itself.

Furthermore, a concavely depressed portion 75 is formed in the middle of the upper surface of the cover 70 with respect to the front-back direction. The depressed portion 75 is disposed at a position back on to the protrusion 71 and has a fifth horizontal surface 76 substantially in parallel to the first horizontal surface 72 and a third vertical surface 77 substantially in parallel to the first vertical surface 74. The third vertical surface 77 has a height (a depth of the recess 75) that is substantially equal to the thickness of the cover 70. Accordingly, the thickness of the cover 70 is substantially constant over its entirety including a forming region of the recess 61 and the protrusion 71.

Subsequently, a method of manufacturing the terminal box of the embodiment and operation/working effect of the terminal box will be described. The terminal boards 10 are supported on the upper surface of the bottom wall 51 in the box main body 50. The bypass diodes 30 are connected to the terminal boards 10 except for the above-mentioned other relay connecting terminal 10B. Furthermore, the cables 90 are connected to both cable connecting terminals 10A respectively. Next, the box main body 50 is mounted to the mounting surface of the solar cell module by an adhesive agent or the like In the course of the mounting, the leads are drawn from the connecting hole 11 into the box main body 50, and the terminals of the drawn leads are connected to the terminal boards 10 respectively. Subsequently, the insulating resin 60 in the molten state is introduced through the opening 58 into the box main body 50.

Subsequently, the cover 70 is attached to the box main body 50 before the insulating resin 60 is hardened. In this case, the peripheral edge of the cover 70 is placed on the stepped portion 55 of the peripheral wall 52 and the cover lock of the cover 70 is locked by the lock supports 54, whereby the cover 70 is fixed to the box main body 50. The protrusion 71 enters the insulating resin 60 in the molten state, and the recess 61 corresponding to the protrusion 71 is formed in the surface of the insulating resin 60 with the flow thereof. Furthermore, the third horizontal surface 62 is formed in a closely adherent relation to the first horizontal surface 72, and the second vertical surface 63 is formed in a closely adherent relation to the first vertical surface 74. Furthermore, the entry of the protrusion 71 into the insulating resin 60 raises a surface position of the insulating resin 60 such that the fourth horizontal surface 64 is disposed higher than the first horizontal surface 72. However, since a space is defined between the second and fourth horizontal surfaces 73 and 64, the surface of the insulating resin 60 is disallowed to adhere closely to the underside of the cover 70. In other words, an amount of insulating resin to be introduced is adjusted so that the space is retained between the second and fourth horizontal surfaces 73 and 64. Even when the insulating resin 60 is subsequently hardened, the protrusion 71 and the recess 61 are retained in a closely adhered relation.

Meanwhile, when the bypass diodes 30 heat up as the result of use, part of heat generated by the bypass diodes 30 is dissipated from the insulating resin 60 through the cover 70 into the atmosphere. In this case, a heat dissipation path from the insulating resin 60 to the cover 70 is desirably ensured since the protrusion 71 and the recess 61 are in abutment with each other and no air space is interposed therebetween. Consequently, the heat generated by the bypass diodes 30 is efficiently dissipated from the insulating resin 60 through the cover 70 into the atmosphere.

In this case, before the insulating resin 60 is hardened, the cover 70 is attached to the box main body 50, and the insulating resin 60 is adhered to the underside of the cover with attachment of the cover 70 to the box main body 50. Consequently, the interposition of air space between the cover 70 and the insulating resin 60 can reliably be prevented by a simple manner.

Furthermore, the protrusion 71 presses the surface of the insulating resin 60 with attachment of the cover 70, whereby the recess 61 is formed in the surface of the insulating resin 60. Accordingly, even when the surface position of the insulating resin 60 rises as the result of the entry of the protrusion 71 into the insulating resin 60, the rise of the surface position is absorbed by the space between the second and fourth horizontal surfaces 73 and 64. Consequently, the insulating resin 60 can be avoided from leaking from the peripheral edge of the cover 70 with attachment of the cover 70

Furthermore, since the depressed portion 75 is formed at the position back on to the protrusion 71 in the surface of the cover 70, an increase in the thickness of the cover 70 can be avoided by the protrusion 71. Accordingly, an occurrence of sink mark during the forming of the cover 70 can be reduced.

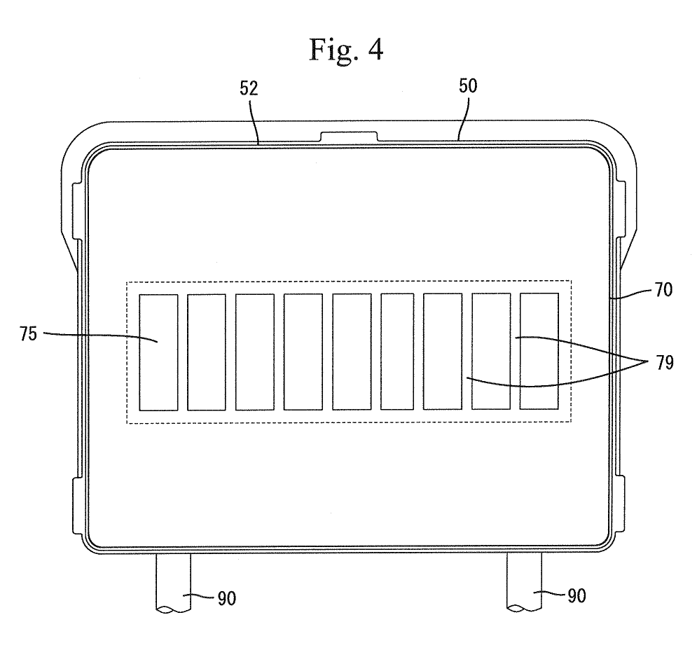

FIG. 4 shows a second embodiment of the invention. In the second embodiment, a plurality of heat dissipation fins 79 is formed so as to rise from the bottom of the depressed portion 75. More specifically, each fin 79 takes the form of a rib extending in the front-back direction and is formed over the entire length of the depressed portion 75 with respect to the front-back direction. Furthermore, the fins 79 are disposed at constant intervals in the widthwise direction, and the depressed portion 75 is divided into a plurality of chambers by the fins 79. Consequently, heat dissipation from the cover 70 into the atmosphere can further efficiently carried out since the heat dissipation fins 79 are formed in the depressed portion 75.

The invention should not be limited by the embodiments described above with reference to the drawings, and the following embodiments encompass the technical scope of the invention:

The protrusion may be formed independent of the cover. For example, the protrusion may comprise a material with a good heat transfer property, such as a metal member.

Regarding the method of manufacturing the terminal box for the solar cell module, the insulating resin may be introduced into the box and the cover may be attached to the box main body before the insulating resin is hardened and the insulating resin may be adhered to the underside of the cover with attachment of the cover. The protrusion may not be necessarily formed in the cover and the recess may not be necessarily formed on the insulating resin.

The structure of the interior of the box main body may only houses the terminal boards and the bypass diodes and is not limited in particular, and a concrete construction thereof is arbitrary.

1. A terminal box for use with a solar cell module, which is mounted on a solar cell module, the terminal box comprising:
a plurality of terminal boards;
at least one bypass rectifying device for reverse load, connected to the corresponding terminal boards;
a box main body housing the rectifying device and the terminal boards and having an open side;
a cover which is attached to the box main body so as to cover the open side of the box main body and has an underside having a protrusion; and
an insulating resin which is introduced into the box main body before the cover is attached to the box main body, the insulating resin having a surface formed with a recess which is abutted along an outer surface of the protrusion when the cover is attached to the box main body.

2. The terminal box according to claim 1, wherein the protrusion is formed integrally with the cover.

3. The terminal box according to claim 2, wherein the cover has a surface having a depressed portion formed at a position opposed to the protrusion.

4. The terminal box according to claim 3, wherein the depressed portion has heat dissipation fins formed therein.

5. The terminal box according to claim 1, wherein the protrusion and the recess are disposed at respective positions opposed to the rectifying device.

6. The terminal box according to claim 5, wherein the at least one rectifying device comprises a plurality of rectifying devices, the rectifying devices being lined in one direction in the box main body, and the protrusion and the recess are formed to be elongate in one direction so as to collectively surround the rectifying devices.

7. The terminal box according to claim 5, wherein the rectifying device is supported on one of the terminal boards, and said one terminal board has a supporting portion on which the rectifying device is supported, the supporting portion having a level raised to the protrusion side.

8. A method of manufacturing a terminal box for use with a solar cell module, the terminal box comprising a plurality of terminal boards, a bypass rectifying device for reverse load, connected to the corresponding terminal boards, a box main body housing the rectifying device and the terminal boards and having an open side, a cover which is attached to the box main body so as to cover the open side, the method comprising: introducing an insulating resin into the box main body; and
attaching the cover to the box main body before the insulating resin is hardened and adhering the insulating resin to an underside of the cover with attachment of the cover to the box main body.

9. The method according to claim 8, wherein the cover has an underside formed with a protrusion, and the protrusion presses a surface of the insulating resin with attachment of the cover to the box main body, whereby a recess is formed in a surface of the insulating resin.

10. The method according to claim 9, wherein an amount of the insulating resin introduced into the box main body is adjusted so that an interspace is defined between a part of the underside of the cover other than the protrusion and a part of the surface of the insulating resin other than the recess with the cover having being attached to the box main body.
